(19) United States
(12) Patent Application Publication
(10) Pub. No.: US 2025/0087499 A1
(43) Pub. Date: Mar. 13, 2025

(54) Semiconductor Device and Method of Making a Fine Pitch Organic Interposer with Dual Function Capping Layer

(71) Applicant: STATS ChipPAC Pte. Ltd., Singapore (SG)

(72) Inventors: Kirak Son, Incheon (KR); JungHwan Jang, Incheon (KR); KyungHan Ryu, Incheon (KR); MyongSuk Kang, Incheon (KR); JaeSeong Choi, Gyeonggi-do (KR); YoungJoon Yoon, Seoul (KR)

(73) Assignee: STATS ChipPAC Pte. Ltd., Singapore (SG)

(21) Appl. No.: 18/463,613

(22) Filed: Sep. 8, 2023

(51) Int. Cl. H01L 21/48; H01L 23/498

(52) U.S. Cl. CPC H01L 21/4857; H01L 23/49822; H01L 23/49894; H01L 23/3128; H01L 24/13; H01L 24/16; H01L 24/32; H01L 24/73; H01L 24/81; H01L 24/83; H01L 24/92; H01L 25/18; H01L 2224/13082; H01L 2224/16238; H01L 2224/32225; H01L 2224/73204; H01L 2224/81005; H01L 2224/83005; H01L 2224/92125; H01L 2924/1433; H01L 2924/14361; H10B 80/00

(57) ABSTRACT

A semiconductor device has a carrier. A first redistribution layer is formed over the carrier. A capping layer is formed on the first redistribution layer. The capping layer includes an anti-reflective coating. An insulating layer is formed on the capping layer. An opening is formed through the insulating layer using photolithography. A conductive layer is formed in the opening.

### FIELD OF THE INVENTION

The present invention relates in general to semiconductor devices and, more particularly, to a semiconductor device and method of making a fine pitch organic interposer with dual function capping layer.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, power conversion, photo-electric, and creating visual images for television displays. Semiconductor devices are found in the fields of communications, networks, computers, entertainment, and consumer products. Semiconductor devices are also found in military applications, aviation, automotive, industrial controllers, and office equipment.

Semiconductor device manufacturers are continually striving to make smaller semiconductor devices to meet the demands of electronic device manufacturers and consumers alike. As the density of components within semiconductor packages increases, the redistribution layers (RDL) used in semiconductor packages must have conductors with smaller cross-sectional dimensions, e.g., width and height. The smaller RDL cross-sectional area increases current density and causes electromigration issues, where molecules of the conductor migrate away from the desired location for the RDL. Therefore, a need exists for semiconductor manufacturing methods and semiconductor devices that are less susceptible to electromigration.

### BRIEF DESCRIPTION OF THE DRAWINGS

FIGS. 1a-1c illustrate a semiconductor wafer with a plurality of semiconductor die separated by a saw street;

FIGS. 2a-2r illustrate a process of forming a semiconductor package with fine pitch organic interposer utilizing a dual-function capping layer; and

FIGS. 3a and 3b illustrate integrating the semiconductor packages into an electronic device.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the semiconductor package. The electrical connections can be made with conductive layers, bumps, stud bumps, conductive paste, or wirebonds. An encapsulant or other molding material is deposited over the semiconductor package to provide physical support and electrical isolation. The finished semiconductor package is then inserted into an electrical system and the functionality of the semiconductor device is made available to the other system components.

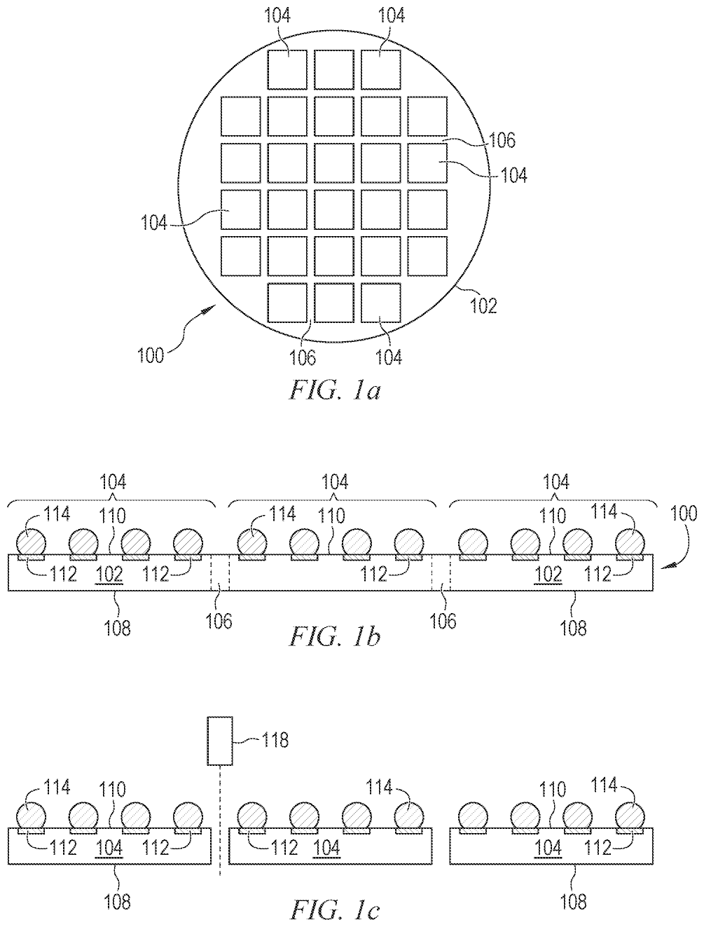

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

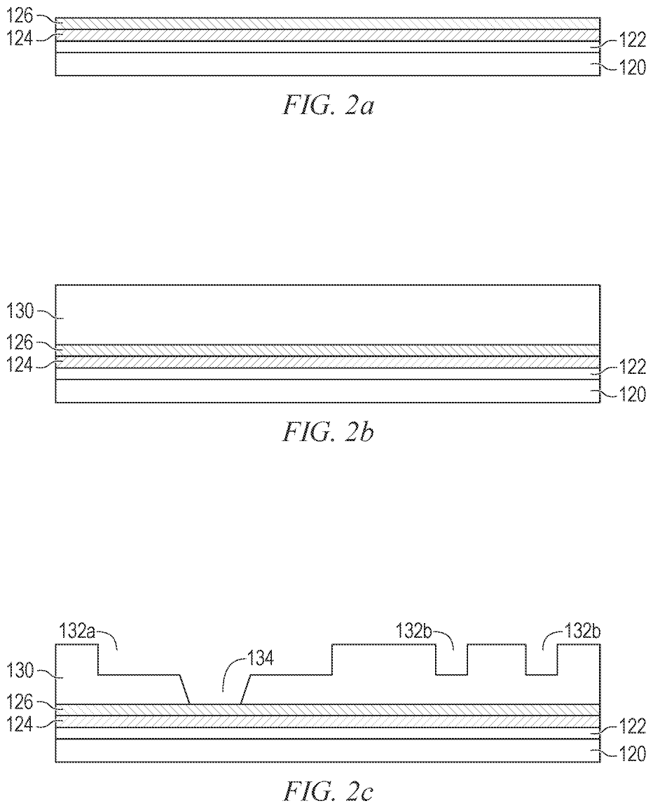

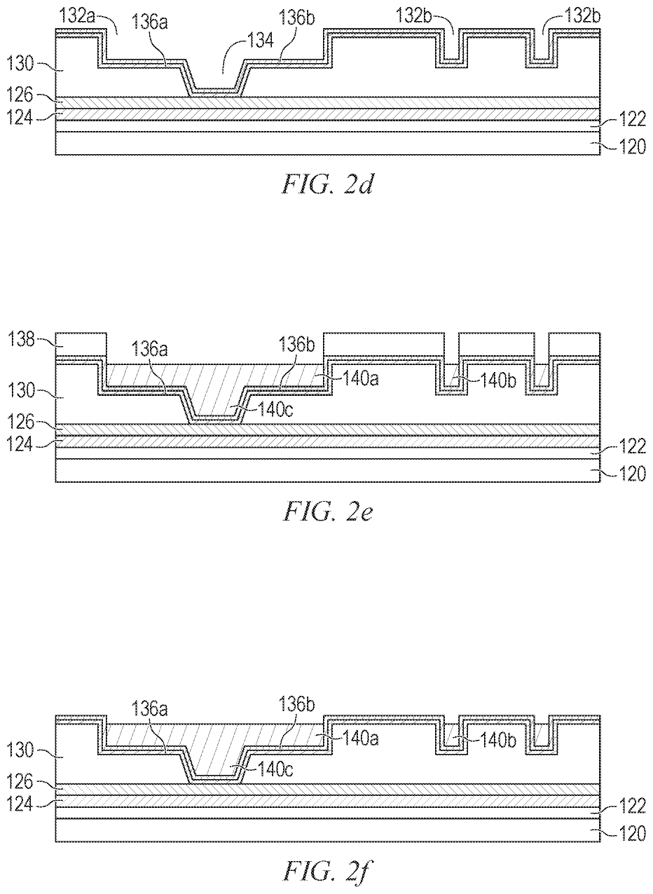

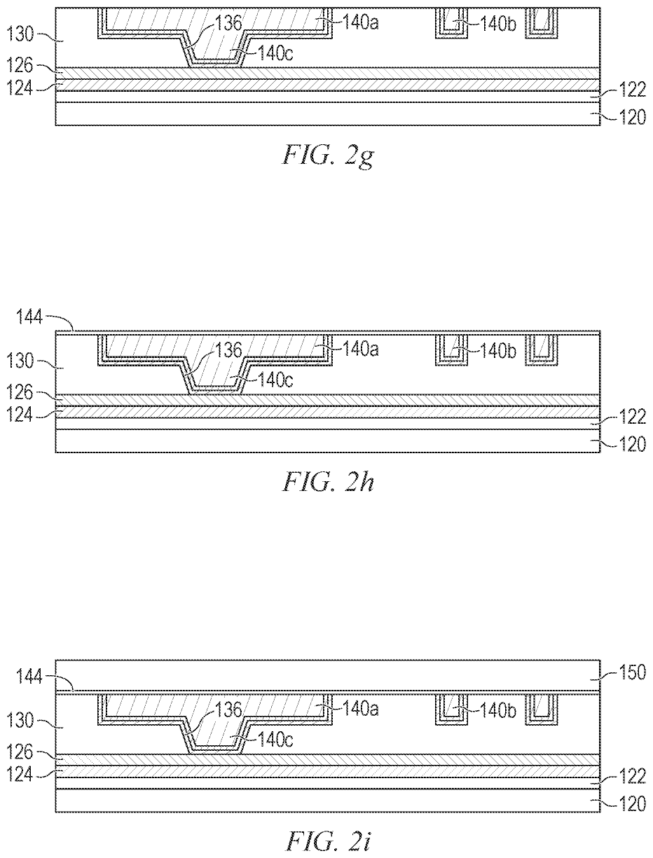

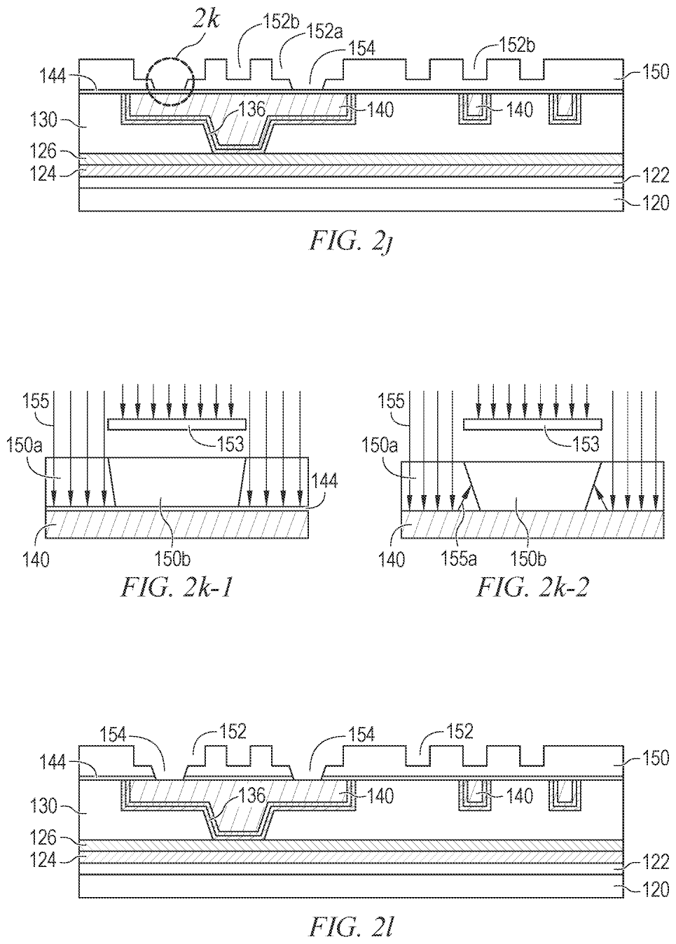

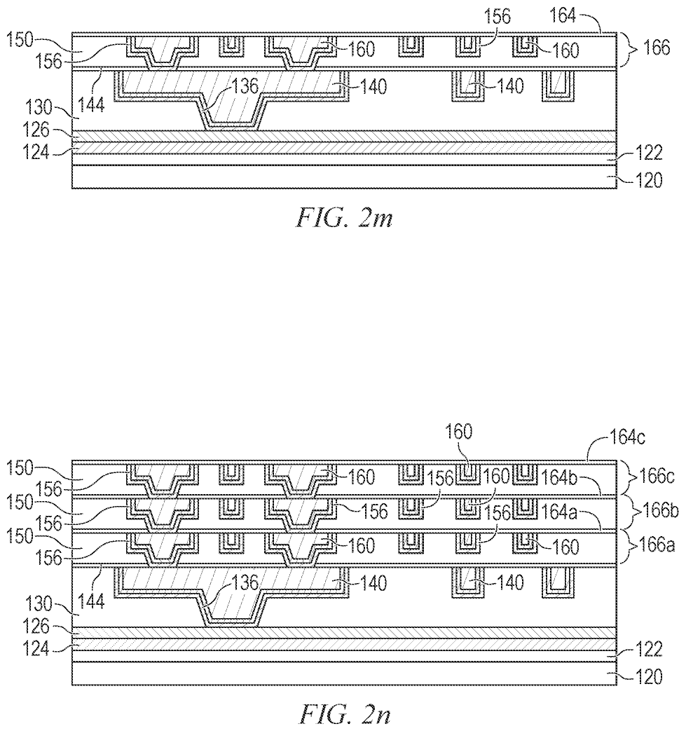

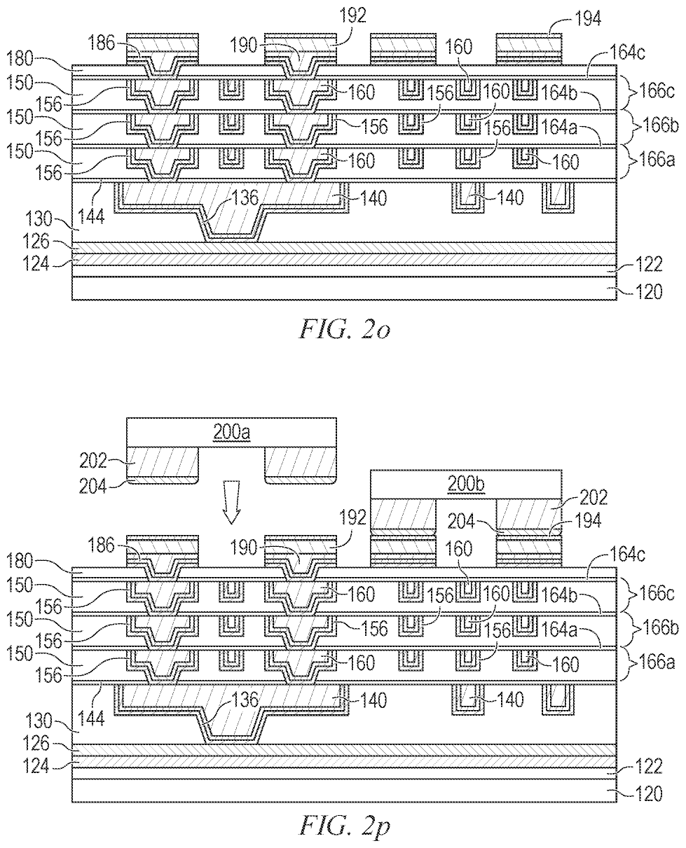

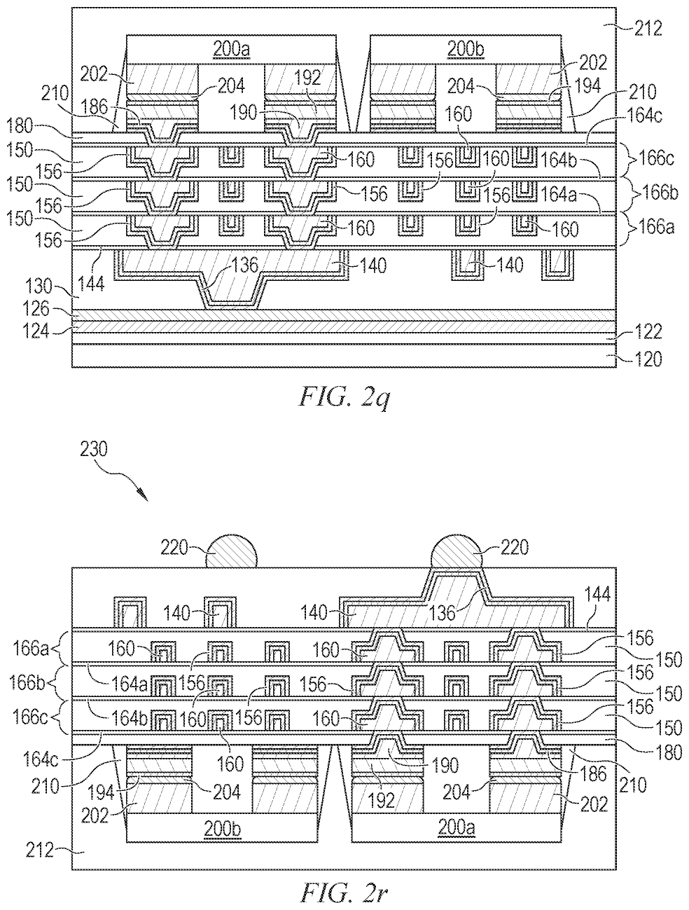

FIGS. 2a-2r illustrate a process of forming a semiconductor package with a fine-pitched organic interposer utilizing a dual-function capping layer. FIG. 2a shows a carrier 120 containing sacrificial base material such as silicon, polymer, beryllium oxide, glass, or other suitable low-cost, rigid material for structural support. While carrier 120 is shown as being sized for manufacturing a single unit, a larger carrier suitable for forming hundreds or thousands of units at a time is typically used. The units are singulated from each other near the end of the manufacturing process.

A temporary bonding (TB) material 122, e.g., a thermal or ultraviolet (UV) release layer, is disposed on carrier 120. TB material 122 can be a liquid adhesive dispensed over carrier 120 or a tape cut to the size of the carrier and disposed onto the carrier.

A metal adhesion layer 124 is formed over TB material 122. Adhesion layer 124 can be one or more layers of Al, Cu, Sn, Ni, Au, Ag, titanium (Ti), tantalum (Ta), chromium (Cr), or other suitable electrically conductive material. In some embodiments, the material for adhesion layer 124 is selected from a set consisting of Al, Ti/Cu, Ta/Cu, Cr, and Ni. Adhesion layer 124 can be formed using PVD, CVD, electrolytic plating, electroless plating, or another suitable metal deposition process. A second metal layer 126 is formed over adhesion layer 124. Metal layer 126 is formed of similar materials and in similar processes as adhesion layer 124. In combination, adhesion layer 124 and metal layer 126 operate as laser blocking layers during debonding from carrier 120.

In FIG. 2b, an insulating layer 130 is formed over carrier 120, TB material 122, adhesion layer 124, and metal layer 126. Insulating layer 130 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), benzocyclobutene (BCB), polybenzoxazoles (PBO), FR-4 and other material having similar insulating and structural properties. Insulating layer 130 can be formed using PVD, CVD, printing, lamination, spin coating, spray coating, sintering, or thermal oxidation.

In FIG. 2c, openings 132 and 134 are formed into and through insulating layer 130 using photolithography. In some embodiments, insulating layer 130 is a photosensitive polyimide (PSPI) photo resist layer and etched by exposing the insulating layer to UV light through a mask, developing, and washing away undesired portions. Openings 132 form a redistribution layer (RDL) pattern including contact pads 132a and conductive traces 132b. Contact pads 132a are areas wide enough to ensure that underlying or overlying conductive layers are able to physically and electrically contact the conductive layer being formed. Conductive traces 132b form an RDL pattern to fan-in or fan-out electrical interconnections between layers.

Openings 132 are formed only partially through insulating layer 130 to form a horizontally oriented conductive layer. Openings 134 are formed completely through photoresist layer 130 within openings 132 to provide vertical interconnect for the conductive layer being formed. Openings 134 provide locations for the conductive layer to be exposed for external interconnect after adhesion layer 124 and metal layer 126 are removed. In some embodiments, openings 132 are formed in a first etching step and openings 134 are formed in a second etching step. Etching can be by laser ablation, chemical etching, photolithography, or another suitable means.

In FIG. 2d, a seed layer 136 for the conductive layer is formed over insulating layer 130. Seed layer 136 is formed conformally to include a uniform thickness over all top and side surfaces of insulating layer 130 including within openings 132 and 134. Seed layer 136 includes an adhesion layer 136a and a seed layer 136b formed over the adhesion layer. Adhesion layer 136a is typically formed of Ti and seed layer 136b is typically formed of Cu, but any other suitable material is used in other embodiments. Seed layer 136 can include more or less than two layers in other embodiments. Seed layer 136 is formed using PVD, CVD, electrolytic plating, electroless plating, or another suitable metal deposition process.

In FIG. 2e, a photoresist layer 138 is formed over seed layer 136. Photoresist layer 138 is patterned by light exposure, development, and rinsing to include openings aligning to openings 132 and 134 of insulating layer 130. A conductive material is plated over seed layer 136 and photoresist layer 138 to form a conductive layer 140. Conductive material is deposited over photoresist layer 138 but not illustrated as said conductive material is removed with the photoresist layer, as shown in FIG. 2f, to leave conductive layer 140 formed just within the openings of insulating layer 130.

Conductive layer 140 includes contact pads 140a formed within openings 132a, conductive traces 140b formed within openings 132b, and conductive vias 140c formed within openings 134. Conductive layer 140 is shown in a simplified form for ease of illustration and can be formed with any number of contact pads and any suitable pattern of conductive traces as needed to implement the desired electrical functionality of the package being formed.

In FIG. 2g, the top surface is planarized to remove seed layer 136 from the topmost surface of insulating layer 130, thereby electrically isolating the discrete portions of conductive layer 140 from each other. Planarization can be by a mechanical grinder, laser ablation, chemical-mechanical planarization (CMP), or another suitable means.

In FIG. 2h, a capping layer 144 is formed over insulating layer 130 and conductive layer 140. Capping layer 144 is formed of an insulating material with good adhesion to conductive layer 140 (which is typically Cu) and insulating layer 130 (which is typically PI). Some potential materials for capping layer 144 include Al₂O₃, titanium dioxide (TiO₂), chromium (IV) oxide (CrO₂), and zinc oxide (ZnO). Capping layer 144 can be formed by PVD, CVD, or another suitable method. Silane coupling agents, spin-on glass, or spin-on carbon can also be used and deposited as a spin-coated liquid, which may be preferred if PVD or CVD processes are not available, e.g., due to high outgassing.

In FIG. 2i, insulating layer 150 is formed over capping layer 144. Insulating layer 150 can be formed from any of the materials and using any of the methods discussed above for insulating layer 130. In one embodiment, insulating layer 150 is a PSPI layer.

Openings 152 and 154 are formed through insulating layer 150 in FIG. 2j. Openings 152 and 154 are formed as described above for openings 132 and 134. Openings 152 are formed only partially through insulating layer 150 and shaped as contact pads 152a and conductive traces 152b. Openings 152 are patterned as desired to redistribute electrical signals across the device footprint. Openings 154 are vias completely through insulating layer 150 for eventual electrical connection to underlying contact pads of conductive layer 140. In one embodiment, openings 152 are formed in a first etching step, and then openings 154 are formed afterwards in a second etching step.

FIG. 2k illustrates one embodiment where insulating layer 150 is a PSPI layer and openings 152 and 154 are formed by a photolithography process. FIG. 2k-1 shows photolithography in the present embodiment while FIG. 2k-2 shows photolithography in a hypothetical embodiment without capping layer 144 for the purpose of comparison. A mask 153 is disposed over insulating layer 150 with the desired pattern for openings 154. An ultraviolet light (commonly 365 nanometers) is shone onto mask 153 and insulating layer 150 as illustrated by light rays 155. Mask 153 blocks light rays 155 from hitting insulating layer 150 where openings 154 are desired.

The light rays 155 that hit insulating layer 150 modify the molecular structure of the insulating layer to form a hardened area 150a, while the insulating layer within area 150b remains softer. After exposure to UV light and development, portion 150b is relatively easy to remove in a process that leaves portion 150a in place, thus creating via 154.

Capping layer 144 is a material that absorbs ultraviolet light at the wavelength being used, e.g., 365 nm. Other types of anti-reflective coatings are used in other embodiments, e.g., index-matching, single-layer interference, or multi-layer interference. FIG. 2k-2 shows that, without capping layer 144, light rays 155 reflect off of conductive layer 140 as illustrated by light ray 155a. Some of the reflected light rays 155a travel into the area under mask 153 and cure some of insulating layer 150 that was desired to be removed for opening 154. The reflected rays 155a result in cured area 150a extending further inward, and therefore the resulting opening 154 being smaller. Controlling the critical dimension or diameter of opening 154 is more difficult without capping layer 144 because reflected light rays 155a are not easily controllable. Capping layer 144 absorbing instead of reflecting at least a portion of light rays 155 in FIG. 2k-1 makes a more vertically oriented border between areas 150a and 150b, and therefore a diameter of opening 154 is closer to the size of mask 153.

Capping layer 144 makes it easier to control the critical dimension size for opening 154. In addition, capping layer 144 improves adhesion between insulating layers 130 and 150. Thus, capping layer 144 is referred to as dual function. The adhesion aspect also helps reduce electromigration of the conductive material of conductive traces 140b in addition to helping reduce peeling between insulating layers 130 and 150. Opening 154 is just one example of when the anti-reflective aspect of capping layer 144 provides a benefit. Essentially all photolithography is affected.

In FIG. 2l, the portions of capping layer 144 exposed within openings 154 are removed to expose the underlying portion of conductive layer 140. Capping layer 144 can be wet or dry etched depending on the specific material used. Dry etching can be done with Ar, O₂, N₂, CF₄, or another suitable etchant. Capping layer 144 remains as an adhesion layer between insulating layers 130 and 150 but is removed where necessary to provide an electrical connection to conductive layer 140.

A conductive layer is formed over insulating layer 150 in FIG. 2m in a similar manner as described above for conductive layer 140. Seed layer 156 has a similar structure to seed layer 136, e.g., a Ti adhesion layer and Cu seed layer. Seed layer 156 is formed completely covering insulating layer 150 and then removed except within openings 152 and 154. Seed layer 156 physically and electrically contacts conductive layer 140 at the bottom of openings 154. Openings 152 and 154 are filled with conductive material to form conductive layer 160.

A capping layer 164 is formed over insulating layer 150 and conductive layer 160. Capping layer 164 has similar material and qualities as described above for capping layer 144. Capping layer 164 also has dual use as both an adhesion layer and an anti-reflective coating. Insulating layer 150 and conductive layer 160 in combination form an RDL layer 166. Any number of RDL layers 166 can be formed successively to meet routing requirements of the specific device being manufactured, including forming no RDL layers 166 and leaving conductive layer 140 as the only RDL layer.

FIG. 2n shows three RDL layers 166a-166c formed over conductive layer 140, which is part of a first RDL layer. Each RDL layer 166a-166c includes a capping layer 164 formed on the layer to provide the dual functions for that RDL layer. To simplify illustration, RDL layers 166a-166c are shown as being identical. However, in most embodiments there will be a different routing layout between the different RDL layers. In some embodiments, RDL pitch, spacing, or material composition is different between RDL layers 166a-166c.

In FIG. 20, contact pads are formed over RDL layers 166 for mounting of components. An insulating layer 180 is first formed over capping layer 164c as described above for insulating layers 150. Openings are formed through insulating layer 180 and capping layer 164c for connection of the contact pads to the underlying conductive layer 160 of RDL layer 166c. Seed layer 186 is formed as described above for seed layers 136 and 156. Contact pads 190 are formed on seed layer 186 as described for conductive layers 140 and 160. Contact pads 192 are formed on contact pads 190. Contact pads 192 are formed of any of the materials and any of the methods described above for conductive layers. A solder wetting layer 194 is formed on contact pads 192. Solder wetting layer 194 is formed of any of the materials and any of the methods described above for conductive layers.

In FIG. 2p, semiconductor die 200 are mounted onto contact pads 190-194. Semiconductor die 200a and 200b can be identical or serve different complementary functions. In one embodiment, semiconductor die 200a is an application specific integrated circuit (ASIC) and semiconductor die 200b is a high bandwidth memory (HBM) chip used by the ASIC. Semiconductor die 200 are formed similarly to semiconductor die 104 above. Conductive pillars 202 are formed on contact pads of semiconductor die 200. Solder caps 204 are formed on conductive pillars 202. With semiconductor die 200 disposed on contact pads 190-194, solder caps 204 are reflowed to mechanically couple the semiconductor die to the underlying contact pads. Any other desired electrical components can be mounted onto contact pads 190-194 in addition to, or instead of, semiconductor die 200, e.g., discrete active or passive components.

In FIG. 2q, an underfill 210 is dispensed under semiconductor die 200. Underfill 210 can alternatively be applied on top of insulating layer 180 and contact pads 190-194, or on semiconductor die 200, before disposing the semiconductor die onto the contact pads. Encapsulant or molding compound 212 is deposited over and around semiconductor die 200 using a paste printing, compressive molding, transfer molding, liquid encapsulant molding, vacuum lamination, spin coating, or another suitable applicator. Encapsulant 212 can be liquid or granular polymer composite material, such as epoxy resin, epoxy acrylate, or another suitable polymer, with or without a suitable filler. Encapsulant 212 is non-conductive, provides structural support, and environmentally protects the semiconductor device from external elements and contaminants.

In FIG. 2r, the panel is flipped and carrier 120, TB material 122, adhesion layer 124, and metal layer 126 are removed. A laser is used on carrier 120 to reduce the adhesion of TB material 122, thereby allowing the carrier to be removed. Adhesion layer 124 and metal layer 126 block the laser from impacting the overlying layers and devices. Once carrier 120 is removed, adhesion layer 124 and metal layer 126 are removed by chemical etching, laser ablation, CMP, or another suitable process.

Solder bumps 220 are formed on the now-exposed portions of conductive layer 140 or seed layer 136. Solder bumps 220 are formed as described above for bumps 114. A second bump 220 is illustrated in FIG. 2r as being on an exposed portion of seed layer 136 that is only visible in another cross-section. FIG. 2r shows a completed semiconductor package 230. When a panel of multiple devices is formed at once, the devices are singulated from each other using a saw blade, laser cutting tool, or other suitable means.

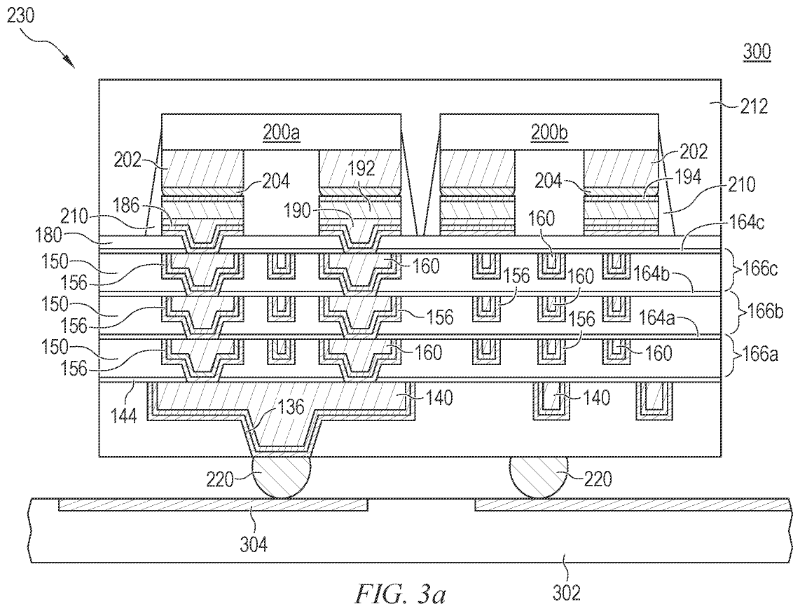

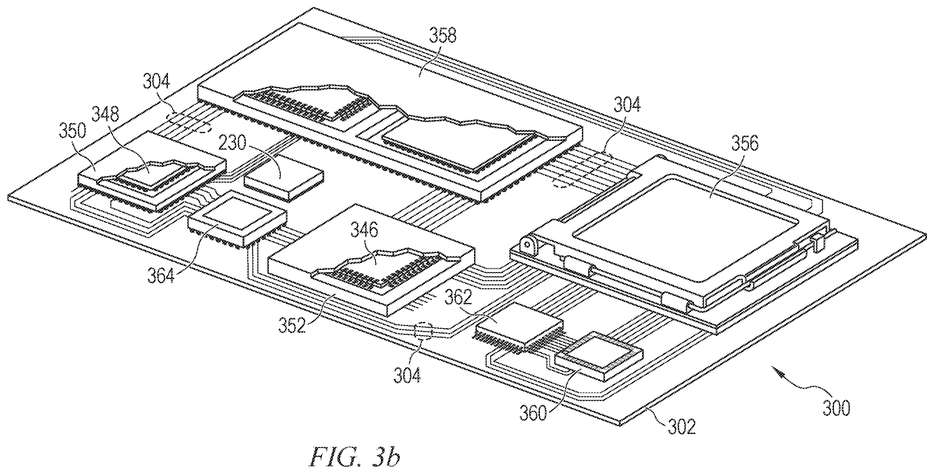

FIGS. 3a and 3b illustrate integrating the above-described semiconductor packages and devices, e.g., semiconductor package 230, into a larger electronic device 300. FIG. 3a illustrates a partial cross-section of semiconductor package 230 mounted onto a printed circuit board (PCB) or other substrate 302 as part of electronic device 300. Bumps 220 are reflowed onto conductive layer 304 of PCB 302 to physically attach and electrically connect semiconductor package 230 to the PCB. In other embodiments, thermocompression or other suitable attachment and connection methods are used. In some embodiments, an adhesive or underfill layer is used between semiconductor package 230 and PCB 302. Semiconductor die 200 are electrically coupled to conductive layer 304 through conductive layers 140 and 160.

FIG. 3b illustrates electronic device 300 having a chip carrier substrate or PCB 302 with a plurality of semiconductor packages disposed on a surface of PCB 302, including semiconductor package 230. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 3b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a carrier;
forming a first redistribution layer over the carrier;
forming a capping layer on the first redistribution layer;
forming an insulating layer on the capping layer;
forming an opening through the insulating layer using photolithography; and
forming a conductive layer in the opening.

2. The method of claim 1, wherein the capping layer includes an anti-reflective coating.

3. The method of claim 1, wherein the capping layer includes Al₂O₃, TiO₂, CrO₂, or ZnO and is deposited by physical vapor deposition (PVD) or chemical vapor deposition (CVD).

4. The method of claim 1, wherein the capping layer includes a silane coupling agent, spin-on carbon, or spin-on glass and is deposited by spin coating.

5. The method of claim 1, further including forming an opening through the capping layer after forming the opening through the insulating layer.

6. The method of claim 1, further including forming a second capping layer on the insulating layer and conductive layer.

7. A method of making a semiconductor device, comprising:
forming a first redistribution layer;
forming a capping layer on the first redistribution layer; and
forming a second redistribution layer on the capping layer.

8. The method of claim 7, wherein the capping layer includes an anti-reflective coating.

9. The method of claim 7, wherein the capping layer includes Al₂O₃, TiO₂, CrO₂, or ZnO and is deposited by physical vapor deposition (PVD) or chemical vapor deposition (CVD).

10. The method of claim 7, wherein the capping layer includes a silane coupling agent, spin-on carbon, or spin-on glass and is deposited by spin coating.

11. The method of claim 7, wherein the capping layer remains formed directly on a conductive trace of the first redistribution layer after forming the second redistribution layer.

12. The method of claim 7, further including forming a second capping layer on the second redistribution layer.

13. The method of claim 7, wherein the second redistribution layer is coupled to the first redistribution layer through an opening of the capping layer.

14. A semiconductor device, comprising:
a carrier;
a first redistribution layer formed over the carrier;
a capping layer formed on the first redistribution layer;
an insulating layer formed on the capping layer; and
a conductive layer formed over the insulating layer,
wherein the conductive layer is coupled to the first redistribution layer through an opening of the insulating layer and an opening of the capping layer.

15. The semiconductor device of claim 14, wherein the capping layer includes an anti-reflective coating.

16. The semiconductor device of claim 14, wherein the capping layer includes Al₂O₃, TiO₂, CrO₂, or Zno.

17. The semiconductor device of claim 14, wherein the capping layer includes a silane coupling agent, spin-on carbon, or spin-on glass.

18. The semiconductor device of claim 14, wherein the capping layer is formed directly on a conductive trace of the first redistribution layer.

19. The semiconductor device of claim 14, further including a second capping layer formed on the insulating layer and conductive layer.

20. A semiconductor device, comprising:
a first redistribution layer;
a capping layer formed over the first redistribution layer; and
a second redistribution layer formed over the capping layer.

21. The semiconductor device of claim 20, wherein the capping layer includes an anti-reflective coating.

22. The semiconductor device of claim 20, wherein the capping layer includes Al₂O₃, TiO₂, CrO₂, or ZnO.

23. The semiconductor device of claim 20, wherein the capping layer includes a silane coupling agent, spin-on carbon, or spin-on glass.

24. The semiconductor device of claim 20, further including a second capping layer formed over the second redistribution layer.

25. The semiconductor device of claim 20, wherein the second redistribution layer is coupled to the first redistribution layer through an opening of the capping layer.
